(19) United States
(12) Patent Application Publication
(10) Pub. No.: US 2005/0217566 A1
(43) Pub. Date: Oct. 6, 2005

(54) Method for producing one or more monocrystalline layers, each with a different lattice structure, on one plane of a series of layers

(76) Inventors: Siegfried Mantl, JULICH (DE); Bernhard Hollander, Bergisch Gladbach (DE); Quing-Tai Zhao, Julich (DE)

Correspondence Address: THE FIRM OF KARL F ROSS, 5676 RIVERDALE AVENUE, PO BOX 900, RIVERDALE (BRONX), NY, 10471-0900, US

(21) Appl. No.: 10/512,529

(22) PCT Filed: Apr. 22, 2003
(86) PCT No.: PCT/DE03/01315

§ 371 Date: Oct. 21, 2004

(30) Foreign Application Priority Data
Apr. 24, 2002 (DE) 102 18 381.3

(51) Int. Cl. C30B 23/00; C30B 25/00; C30B 28/12; C30B 28/14

(52) U.S. Cl. 117/89

(57) ABSTRACT

The invention relates to a method for producing one or more monocrystalline layers, each with a different lattice structure, on one plane, for an electronic component, in order to produce a system on a chip. The invention also relates to a component containing one or more layers of this type, such as MOSFETs, MODFETs, resonant tunnel diodes and/or photodetectors.

The invention relates to a method of producing one or more monocrystalline layers with respective different lattice structures in one plane of a layer sequence according to the preamble of claim 1. The invention also relates to a component [electronic component] according to the auxiliary claims.

The production of monocrystalline layers is mainly significantly limited by the substrate materials available and which can also determine the reduction in quality of the layer. Different crystal structures as well as different lattice parameters between the substrate and the layer material (lattice defect match) limit as a rule monocrystalline growth of layers of high quality. An especially important example is the application of silicon-germanium alloys (SiGe) alloys) to silicon (Si) for microelectronic components. If monocrystalline layers are deposited without lattice parameter matching, the result is intrinsically. If the deposited layer oversteps a certain degree of stress, the mechanical stress will be relieved by the defect formation and the lattice structure of the deposited layer will approach that of the substrate. This process is called stress relaxation and below will be referred to generally as “relaxation”.

With layer thicknesses of the type mainly used for electronic components such relaxation dislocations at the interface between the forming layer and the substrate can reduce the stresses with the result that there may be a disadvantageous increase in the number of dislocations and the migration of such dislocations from the interface to the layer surface in the form of so-called threading dislocations. Since most of these dislocations propagate further through newly developing or growing layers, there is a distortion of the electrical and optical characteristics of the layer material as a consequence.

The rapid development in the field of information technology has required increasingly more rapid transistors and especially metal oxide field-effect transistors (MOSFETs). An increase in the capacity of these components has as a rule been associated with a reduction in the transistor dimensions. Such a reduction in transistor dimensions with increase in the speed and capacity is however expensive and complex since the key technologies available-for chip production, like the lithography process and the etching process must be replaced by systems which are more compatible with increased capacity. An alternative approach is to improve the properties of the material used and that is offered by the use of stressed silicon and stressed silicon germanium (SiGe).

The use of silicon or silicon germanium (SiGe) in a certain elastic distortion or strain state, improves the material properties and especially the current carrier mobility of the electrons and holes which is permanently important for such components. The use of these and other high value materials enables a significant increase in the performance of silicon-based high-power components like MOSFETs and MODFETs without critical structural dimensional changes of the component.

Since the silicon germanium (SiGe) material system thermodynamically is a completely miscible system, the compound can be formed with optional concentrations of the two components. Silicon and germanium are characterized by identical crystal structures but differ with respect to their lattice parameters by 4.2%, that is a SiGe layer or a pure Ge layer on silicon grows with stress.

In the state of the art for producing for example stress-free qualitatively high levels of silicon germanium (SiGe) alloy layers on a silicon substrate, the use of the so-called graded layer technique has been indicated. In this case SiGe layers are dealt with whose Ge concentration increases continuously or stepwise toward the surface until the desired Ge content is achieved. Since to maintain the layer quality only an increase in the Ge content of about 10 atom % per pm can be used, such layers may have to be up to 10 μm thick to reach desired germanium concentrations. For the layer growth this has not been found to be satisfactory on economical and technological grounds. The layer growth of this “graded” layer is described in E. A. Fitzgerald et al., Thin Solid Films, 294 (1997) 3. However this method generally yields high layer roughnesses in incomplete relaxation.

From DE 198 02 977 a method is known which enables the production of stress-relaxed surface layers with good quality. When the method is applied to silicon germanium, a thin, stress-relieved SiGe buffer layer can be made upon which the epitaxial deposition of a stressed Si layer is possible. This elastic stressed silicon layer has, by comparison with normal silicon, an enhanced electron mobility. As a result it is very interesting for producing small n-channel MOSFETs and n-channel MODFETs.

In order to bring about a significantly improved hole mobility for p-channel components, the simultaneous use of stressed SiGe or Ge is required. In DE 198 02 977 it is proposed to deposit, upon a very thick, graded stress-relaxed SiGe layer, a further thin stressed SiGe layer with higher Ge concentration as well as a thin stressed Si. In principle it will yield stressed Si and stressed silicon germanium (SiGe) for n- and p-channel processing. It is a drawback however that at least three layers must be provided one upon the other since that complicated the overall electronic component technology. In the complicated heterosystem which results, there are formed parallel to the desired channel, parasitic channels which tend to be conductive and which reduce the quality of electronic components. With the multiplying of the layers, especially the presence of very thick, graded, stress-relaxed silicon germanium (SiGe) layers, the overall layer thickness increases so that the thermal conductivity capacity is reduced. In addition because of the thick, graded, stress-relaxed silicon germanium (SiGe) layer, planarity between the Si—Ge region and the substrate surface cannot be ensured.

In Leitz et al (Hole mobility enhancement in strained Si/Si_{1 y}Ge_{y}p-type metal-oxide-semiconductor field-effect transistors grown on relaxed Si₁₋ₓGeₓ(x<y) virtual substrates, 2001. Applied Physics Letters, Vol. 79, 4246-4248 and Cheng et al (Relaxed Silicon-Germanium on insulator (SGOI), Mat. Res. Soc. Symp., Vol. 686, A1.5.1-A1.5.6), method of producing structures with wafer bonding and etching have been proposed. The drawback of these methods include the technologically highly expensive nature since many process steps are required with high demands. The methods described in both references are especially difficult to carry out with large wafers (300 nm and greater) since they require that the layer thicknesses and planarity of the wafer be maintained over a very large area. In addition a bending of the wafer by the stresses generated in bonding must be avoided.

The object of the invention is to provide a method of producing one or more monocrystalline layers each with a different lattice structure in one plane which does not evidence the drawbacks of the state of the art. Especially should different regions with for example stress and unstressed silicon, stressed and unstressed silicon germanium (SiGe) or other suitable materials with respective different lattice structures be provided in the same plane and, while ensuring the planarity which may be required for further processing, for example, for producing a “system on a chip” to be provided.

The objects are achieved by a method according to the main claim and by an electronic component according to the auxiliary claims. Advantageous refinements are given in the patent claims which are respectively dependent therefrom.

For the purposes of the present invention, one starts with a layer sequence with a substrate in the depth of which insulating regions are provided. In the substrate close to the surface there is partially at least one defect region. On the substrate in addition there is at least partially a first epitactic layer. This layer sequence is so treated that only the region of the first epitactic layer above the defect region is stress relaxed while the remaining regions of this layer retain their stressed state.

In this manner one obtains directly at least one first epitactic layer with different stressed states and therewith different lattice structures in one plane on a substrate also with a certain lattice structure. By different lattice structures it should be understood that materials with different lattice parameters or different crystal structures are to be understood.

The mentioned starting layer sequence of substrate, insulating regions, defect regions and first epitactic layer can be obtained in different ways. The first layer can for example be epitactically deposited on a substrate and then insulating regions can be provided in the depth of this layer sequence and partially a defect region below the interface of the deposited layer can be produced. One need not be bound to this sequence in the processing. The production of the starting layer sequence can be varied, for example, in that one can produce the defect region before or after deposition of the first epitactic layer upon the substrate. It is also possible to carry out a lateral epitactic growth of insulating regions on a substrate with suitable materials. It has been found that further layers can be provided for example a thin transition layer between the substrate and the first epitactic layer from the same material as the substrate.

A significant advantage of the method is that one can begin with hole-area layers or layer systems and, depending upon the layout of the microelectronic application, locally produce the defect regions of stress relaxation only at desired locations of a large-area wafer. This advantage layer provides ideal conditions for making a “system on a chip”, that is it alloys active and passive components (transistors of different types, coils, condensers, etc.) to be produced in a single plane.

The defect regions can be produced by ion implantation, preferably with light ions, for example helium (defect implantation) in such manner that ions primarily are present below the first epitactic layer. The layer sequence is so treated thermally, or the thermal budget held so small, that above the implanted region of the substrate the first epitactic layer is stress relaxed and above nonimplanted regions of the substrate, the first epitactic layer regions its stressed state. Bubbles or hollow spaces arise as generated by the implantation, for example with helium and subsequent heat treatment so that dislocations run from the defect region to the first epitactic layer. These dislocations have the effect of locally relaxing the first epitactic layer above the defect region. There arise locally limited thin stress relaxed regions of an epitactic layer with limited crystal defects alongside stressed regions of the layer of the same material which are separated from one another by the insulating regions.

The relaxation can also be effected by an oxidation with O₂ or water. Instead of a purely thermal treatment to form stressed and relaxed regions, the treatment can involve oxidation subsequent to the thermal treatment or a combination of oxidation and thermal treatment on a whole area basis or by means of a temperature-resistant oxidation barrier layer, for example by means of a Si₃N₄ mask. In this connection also the local concentrations of elements which are important to the functioning of the electronic component are significant and can be increased within the first epitactic layer (for example silicon germanium (SiGe). The dislocations which result from the stress relaxation in the implanted regions are laterally blocked from spreading by the insulation regions (for example STI or LOCOS). The sliding of the dislocations upwardly is required for the layer relaxation and occurs only at those locations at which relaxation is desired.

The method utilizes process steps which have become established in silicon technology so that this technology can be transferred also to very large wafers (for example 300 mm Si wafers) which for example as has been recognized that the state of the art is very difficult with the wafer bonding technique. In conjunction therewith, according to the invention at least one further epitactic layer can be deposited on the layer sequence on a whole-area basis or locally, or the first epitactic layer can be partially removed from the surface.

As a result one can obtain directly a layer sequence of two materials as relaxed and stressed states “in one plane”. The initially deposited epitactic layer, as already indicated, exceeds in both stressed states in a single plane and indeed independently of where the defect region is to be produced. The substrate below the first epitactic layer is in the relaxed state. The material of the second deposited layer on the first epitactic layer is in a stressed state. The further layers to be deposited can be composed of the same material as the substrate. The deposited further layers can also be composed of the same material as the first epitactic layer, but preferably with a component of this layer at a different concentration from that in the first epitactic layer therebelow. Since the first epitactic layer is very thin, for example of a thickness less than 50 nanometers, it is ensured that the thermal conductivity within the entire layer sequence can be maintained to an outstanding degree. As a result the formation of a “system on a chip” is possible. The layer sequence of the first epitactic layer and the second layer deposited thereon presents, because of the thickness of the layers, a single layer in approximately a single plane with different lattice structures. By the expression “in one plane” or “in a single plane” it is meant that the height of the steps produced by deposition or etching to the surface of the substrate will not be greater than-approximately the depth of field of the imaging optics of the lithographic process. That ensures that in the course of further processing steps, the planarity within the layer sequence will be sufficient. The layer sequence of a first epitactic layer and optionally other deposited layers has for example a thickness of about 100 to 200 nanometers or is even thinner. The production of a “system on a chip” (different electronic components with different functions in a single plane) is possible. For this purpose, initially the gate dielectric (for example SiO₂) the source and drain contacts, the gate contact and optionally spacers as well as the various doped channel regions, source regions and drain regions can be formed and embedded in a passivation layer or insulating layer. In this manner one is not bound to certain transistor types or electronic components.

As the light ions in the case of ion implantation to produce the defect regions, especially helium should be selected. It is however equally possible to select hydrogen or another element, for example from the group of noble gases, especially argon. These kinds of ions ensure that below the boundary layer the desired dislocations are formed without detriment to the epitactic layer.

In addition, a further implantation to form nucleation sites [seeds] can be provided. To reduce the dose of an implanted He⁺ or H⁺ ions for defect generation, a further implantation for example with silicon or germanium can precede the defect generation. In this manner nucleation nuclei for the bubbles which arise with the helium or hydrogen implantation are formed which promotes the formation of these bubbles. These procedures can also be of advantage when the silicon upon an SOI substrate below a SiGe layer is so thin that, for example, with a helium implantation no bubble layer is produced because of the wide depth distribution of the implanted helium ion. The higher masses of silicon or germanium alloy better localization in the depth. The bubble formation is then effected preferably at the defects produced by the silicon or germanium implantation. Usually with boron, arsenic or phosphorous. These so-called shell or trough implantations, also referred to as retrograde corrugations or wave implantations can be carried out advantageously with the same masks which are already used for the production of the defect regions. In addition, implantations can be carried out to set the threshold voltage of MOSFETs with these masks. This reduces the time and cost of making the components.

After or during the fabrication of the electronic components, for example transistors, at selected insulating regions (of for example STI, deep trench or LOCOS) a trench can be etched at least at one side of an insulating region and at least up to the first epitactic layer. The first epitactic layer (for example of silicon germanium (SiGe) is removed by using a mask, for example by underetching selectively, whereby vertical and optionally laterally buried or trenching etching can result. The remaining material of the insulating region serves during the underetching as a self-adjusting lateral etch stop. By selecting suitable material one can obtain advantageously, a layer sequence which can correspond to “silicon on nothing” (SON). The process is especially advantageous for the production of such a structure. The buried or trench etching can be filled with an insulator, for example SiO₂. In this manner one obtains advantageously a layer sequence corresponding to a silicon on insulator (SOI) or a silicon germanium (SiGe) on insulator structure. The process is thus especially appropriate for the production of such structures.

The invention in a further especially advantageous refinement of the invention can serve for the reduction of the dislocation density in the relaxed and stressed layer. This can be achieved by etching the trenches in the layer with a micrometer spacer, especially of one to 100 micrometers or advantageously by forming buried etch regions which are matched to the electronic component structures and after heat treatment at temperatures above 500° C. are obtained. Threading dislocations in the layer slide at the edge of this region and are thus healed.

### EXAMPLES

In the following, the invention is described in greater detail with respect to several exemplary embodiments and the accompanying Figures.

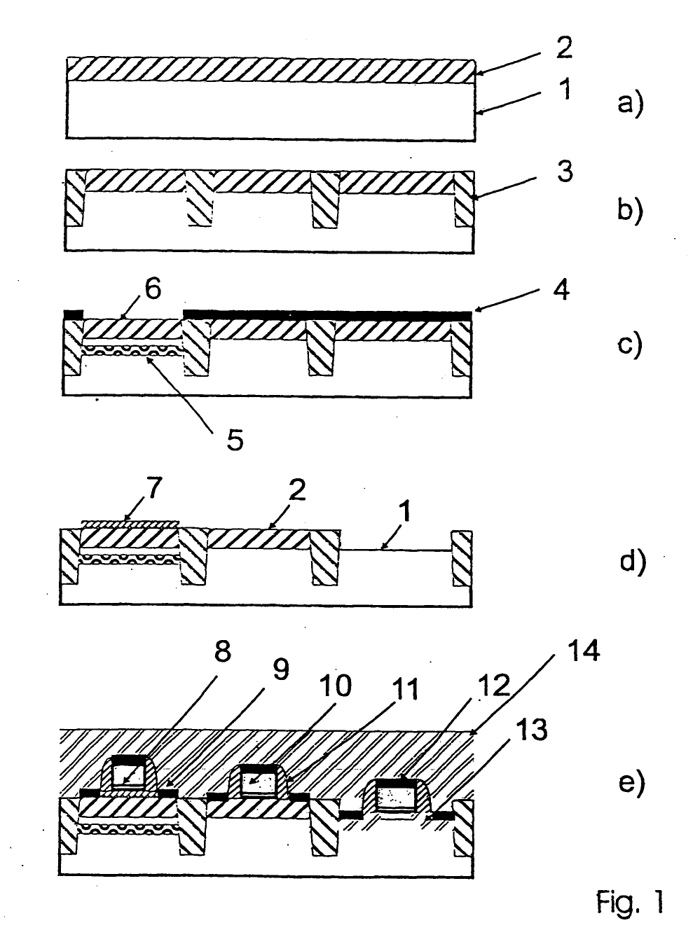

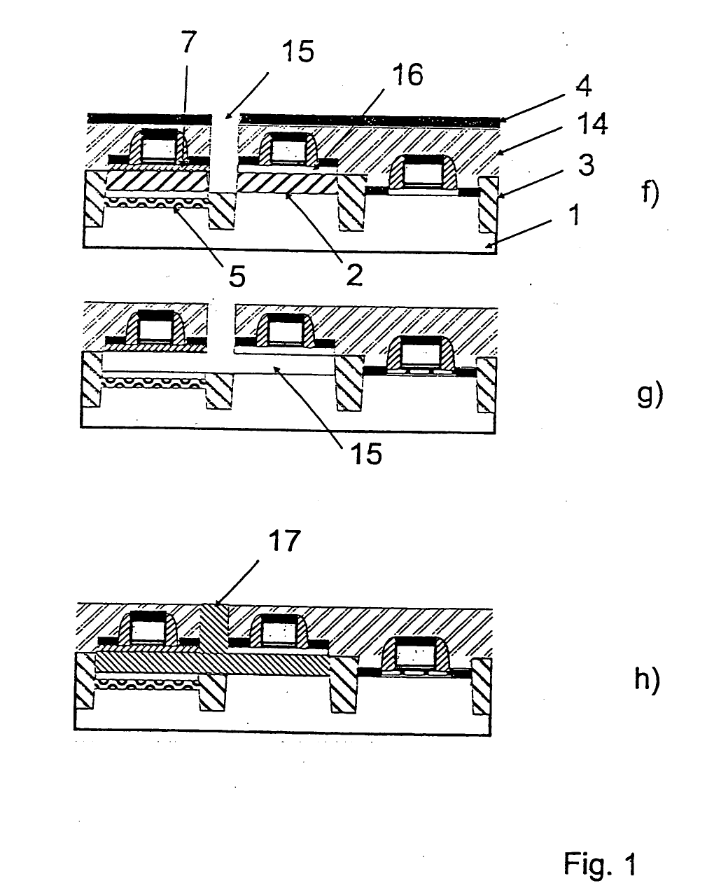

FIG. 1 shows the production of two monocrystalline layers with respective different lattice structures in a single plane. On a silicon substrate 1, a silicon germanium (SiGe) layer 2 is deposited (FIG. 1a). A thin transition layer of silicon can be provided between both layers. Then STI insulation regions 3 are produced in the depth of this layer sequence. In FIG. 1b only the insulating region 3 at the right of all four insulating regions 3 has been marked with an arrow. The four insulating regions 3 serve in subsequent steps of the process in the case of underetching procedures as self-adjusting lateral etch steps. One is not bound to this sequence of steps in the processing. One can also as well start with a commercially-available substrate with fixed insulation regions 3. In such a substrate 1, a defect region 5 can be produced for example by ion implantation or deposition and then the silicon germanium (SiGe) layer 2 can be deposited.

After application of a mask 4, a helium implantation is carried out with an energy of about 18 KeV and a dose of 2×10¹⁶ cm⁻² with 100 nm layer thickness of the silicon germanium (SiGe) layer 2. The mask is removed before the heat treatment as a rule. The implanted ions primarily produce below the silicon germanium (SiGe) layer a defect region 5.

Then the heat treatment is carried out for tempering at 850° C. for 10 minutes in an inert N₂ atmosphere. Other for example inert gases (for example argon) or a gas (for example O₂) which is suitable for the purposes of the invention can be used as well. Above the defect region 5 with this temperature regimen, that should not be selected to be too high, a stressed-relaxed silicon germanium (SiGe) layer 6 is formed. In the region in which the layer sequence is masked by mask 4, following the temperature treatment, stressed silicon germanium (SiGe) 2 is found (FIG. 1d). Part of the previously unmasked silicon germanium (SiGe) layer is removed for example by etching (FIG. 1d: see the removed right-hand part of the layer 2). There an unstressed that is relaxed silicon 1 is found at the surface of the layer sequence.

If the silicon germanium (SiGe) 2 from the beginning in FIG. 1b is deposited over only part of the substrate 1, on the regions of the substrate upon which the silicon germanium (SiGe) has not been deposited, unstressed silicon 1 remains as the substrate at the surface of the layer sequence. Because only a very thin layer of the first deposited layer 2 (silicon germanium (SiGe)) is applied, apart from stressed and relaxed silicon germanium (SiGe) 2, 6, unstressed silicon 1 lie “in one plane”.

In the sense of the invention “one plane”, means that there is sufficient planarity on the various layers 1, 2, 6 for the subsequent method steps (for example for the lithography, as well as a guarantee of thermal conductivity of the substrate 1). Layer sequence according to the invention on the substrate 1 can have a thickness of about 100 to 200 nanometers or less as in the first embodiment in order to achieve these results.

A further layer 7 can be applied epitactically at least partially upon the relaxed silicon germanium (SiGe) layer 6 (FIG. 1d). This additional deposited layer 7 is then stressed. It can, for example, be composed of silicon or also of silicon germanium (SiGe) with a different germanium concentration than in the first epitactic layer 6 therebelow or also can be formed as a multiple layer. In the case of silicon, stressed silicon 7 and unstressed silicon 1 are present “in one plane”. The stressed silicon 7 lies formally indeed above the relaxed silicon germanium (SiGe) layer 6 which again lies alongside the stressed silicon germanium (SiGe) layer 2. Because of the thickness of the layers 2 and 6 however the planarity of the different regions of the layers 1, 2, 6 and 7 as well as the thermal conductivity to the substrate is ensured.

Layer 1 of FIG. 1d (unstressed silicon) can be used for the fabrication of conventional Si components like MOSFETs. Layer 7 of FIG. 1d (stressed silicon) can be used because of the greater mobility of electrons therein for the production of ultrafast MOSFETs and especially n-channel MOSFETs. Layer 2 of FIG. 1d (stressed silicon germanium (SiGe) can be used because of its higher mobility for holes advantageously to produce ultrafast p-channel MOSFETs.

Layer 6 of FIG. 1d (unstressed silicon germanium (SiGe) can be used because of a somewhat higher mobility for holes advantageously for the production of ultrafast p-channel MOSFETs. One can apply other layer sequences thereover and further procedures.

Example: Upon a substrate 1 (for example silicon, silicon germanium (SiGe), sapphire or a suitable perovskite) a lateral epitactic growth of a suitable material (example AlN or silicon germanium (SiGe)is carried out to produce the insulation region.

Apart from silicon germanium (SiGe) as the first epitactic layer 2, in general III-V nitrides (GaN, AlN, InN) as well as oxidic perovskites can be applied as 0 epitactic layer 2. What is improved in every case is that a suitable substrate say that at least one layer 2, 6 with different lattice structures is produced on this substrate separated by the insulating region 3.

The different electronic components, for example transistors, are produced in one plane (system on a chip), FIG. 1b and are embedded in a passivation layer 14. The offset of the electronic components with respect to their heights in FIG. 1e serves exclusively to better illustrate the different processes. In practice the components will lie in the single plane in the sense of the invention.

After fabrication of the electronic components, selectively determined insulation regions 3 or parts thereof can be removed by etching utilizing a further mask 4. The etching is effected initially at least to a depth to the first epitactic layer 2 or 6, for example to its lower edge (FIG. 1f). The result is an initially vertical etched trough 15. Then the stress-relaxed silicon germanium (SiGe) layer 6 and/or the stressed silicon germanium (SiGe) layer 16 in FIG. 1f (for example unstressed silicon) resulting from deposition of silicon on the silicon germanium (SiGe) 2 is not seen in FIG. 1d or FIG. 1e. Mask 4 in FIG. 1c is for this purpose open above the middle part of the layer 2.

By laterally under-etching of the layer 7 (for example stressed silicon) and the layer 16 (for example unstressed silicon, unstressed silicon germanium (SiGe) with a different germanium concentration than that in the layer 2 therebeneath), the layers 2 and 6 are removed and the etched trough 15 advanced horizontally whereby the STI 3 at the sides serves as self-adjusting etch stops (FIG. 1g). This has as a consequence the suppression of the electrical conductivity to the substrate 1.

The formation and spreading of dislocations required for the stress relaxation of the silicon germanium (SiGe) layer 2 is then laterally limited by he insulation regions 3 so that the relaxed silicon germanium (SiGe) layer 6 results. The spreading of the dislocations into neighboring regions is thereby excluded. The etched trough 15 ca be filled with an insulation layer 17, for example, by means of CVD deposition with for example SiO₂ (FIG. 1h) at a later stage. Thus a component with a layer sequence is already formed which laterally has the function of a silicon on insulator (SOI) or a silicon germanium (SiGe) on insulator structure without requiring the use of an expensive substrate.

In the case in which the etching trough 15 in FIG. 1g is only filled in its vertical stretches with the insulator layer 17, a component with a layer sequence is formed which corresponds locally in function to that of a silicon on nothing (SON) substrate.

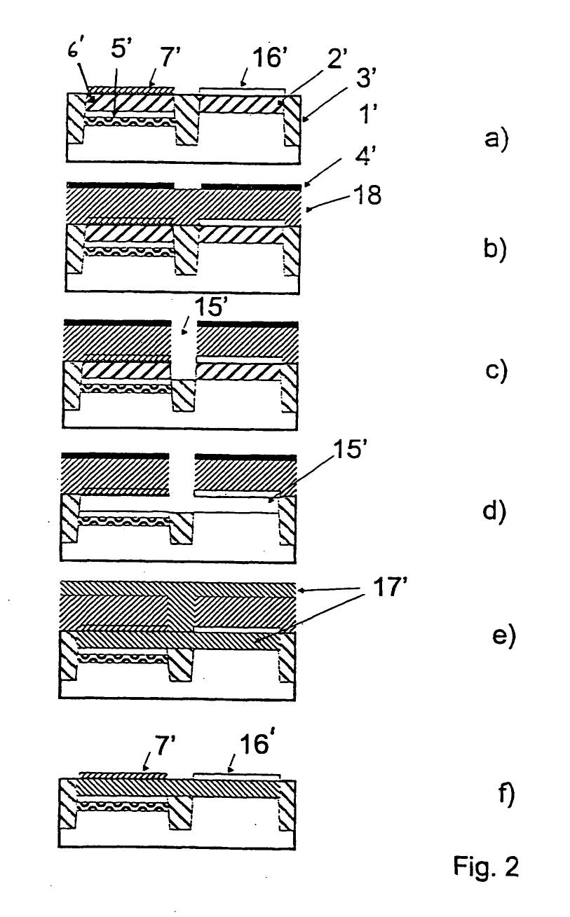

In FIG. 2 only three insulating regions 3 extending in the depth of the layer sequence, have been shown only the right-hand one has been marked with an arrow. FIG. 2a shows, starting from the layer sequence of FIGS. 1c or 1d and the use of mask technology (not shown) the application of a further layer of unstressed silicon 16′ on the layer of stressed silicon germanium (SiGe) 2′. In addition, stressed silicon 7′ is disposed on unstressed relaxed silicon germanium (SiGe) 6′. A stiffening layer 18 and a mask 4′ thereon are arranged on this layer sequence (FIG. 2b). The stiffening layer 18 serves to stabilize the layer sequence. Mask 4, is so arranged that the etched trench 15′ can be etched to the lower edge of the layer 2′ and/or 6′ (FIG. 2c; the reference characteristics of these layers have not been indicated in this Figure and can be deduced from FIG. 2a). Layers 2′ and/or 6′ are removed completely by etching FIG. 2d. The mask 4′ is then removed and the etched trench 15′ is completely filled in both its vertical and horizontal stretches with an insulator 17′. Then the stiffening layer 18 and the insulating material 17′ lying thereon are removed. The result is the layer sequence of 2f.

Then a processing to the electronic component is carried out as described with reference to FIG. 1e until the components, for example, transistors are made.

The difference from the processing in FIG. 1 is that the filling of the etched trench 15′ with the insulator 17′ in FIG. 2 is effected before the electronic component (for example transistors) are made while according to FIG. 1, the different components are initially fabricated and then the etched trench with the insulator 17 is made.

The components illustrated in FIG. 1 are only exemplary as is self-understood. Instead of the illustrated active three components (transistors, passive components of any pipe (coils, condensers, resistors, etc.) can be made in the further processing of the “system on a chip” and integrated therein.

The layer sequence made in accordance with the method of the invention can be applied especially to the production of modulated doped field effect transistors (MODFETs) or metal oxide semiconductor field effect transistors (MOSFETs).

It is also possible to make resonant tunnel diodes, especially a resonant silicon germanium (SiGe) tunnel diode.

Further it is conceivable to produce the photo detector from one of the layer sequences. It is also conceivable, starting from a layer sequence with GaAs as the second deposited layer 7, 7′ on a first epitactic layer of silicon germanium (SiGe) 2,2′, 6, 6′, to make a laser.

### REFERENCE CHARACTER LIST

1. 1′ Substrate
1. 2′ Epitactic layer (for example silicon germanium)
3. 3′ Shallow trench insulation (STI) for example of SiO₂
4. 4′ Photolacquer mask
5. 5′ Defect region
6. 6′ Stress-relaxed layer of the material of the first epitactic layer (for example SiGe)
7. 7′ Deposited silicon layer or silicon germanium layer or multiple layer, for example stressed silicon
8 Gate dielectric for example SiO₂ or alternative gate dielectric
9 Metallic source or drain contact, for example CoSi₂, NiSi, TiSi₂ or other suitable materials
10 Polysilicon or metallic gate contact
11 Spacer, for example SiO₂ and/or SiN
12 Metallic gate contact, for example CoSi₂, NiSi
13 Doped source or drain region
14 Passivation layer or insulation layer
15, 15′ Etched slot or trench
16, 16′ Unstressed silicon or silicon germanium (SiGe) of a different germanium concentration as is optionally the case in layer 2
17, 17′ Insulator (for example SiO₂)
18 Stiffening layer

1. A method of producing one or more monocrystalline layers with respective different lattice structures in one plane of a layer sequence comprising
s substrate (1, 1′) and
an insulation region (3,3′) which extends from the surface into the depth of the substrate (1,1′), whereby
proximal to the surface of the substrate (1,1′) partially at least one defect region (5, 5′) is arranged, and
on the surface of the substrate (1, 1′) partially at least one defect region (5, 5′) is arranged, and
on the surface of the substrate at least partially a first epitactic layer (2,2′) is arranged,
characterized in that
the layer sequence is so treated that only a region (6,6′) of the first epitactic layer (2,2′) after the treatment is stress-relaxed above the defect region (5, 5′) while the remaining regions of the first epitactic layer (2, 2′) retain their stressed state.

2. The method according to claim 1 characterized in that the layer sequence is subjected to a thermal treatment or an oxidation of the layer sequence or to a combination of a thermal treatment and oxidation.

3. The method according to claim 1 characterized in that the layer sequence is subjected to an ion transplantation to produce the defect region (5, 5′) below the first epitactic layer (2, 2′).

4. The method according to claim 1 characterized in that the first epitactic layer (2, 2′, 6, 6′) is at least partially removed.

5. The method according to claim 1 characterized in that at least a further second epitactic layer (7, 7′) is deposited on the layer sequence over the entire area or over locally limited regions.

6. n The method according to one of claim 1 characterized in that a stiffening layer (18) is deposited upon the layer sequence (7, 7′).

7. The method according to claim 6 characterized in that a mask (4′) is deposited upon the stiffening layer (18).

8. The method according to claim 3 characterized in that helium is selected as a light ion for producing the defect region.

9. The method according to claim 3 characterized in that for the ion implantation hydrogen, boron, phosphorous, arsenic, silicon, germanium, antimony, sulfur, neon, argon or xenon ions are used to produce the defect region (5, 5′).

10. The method according to claim 3 characterized in that prior to the helium or hydrogen implantation an implantation for example with silicon, germanium or inert gas is carried out for the nucleation of helium or hydrogen bubbles.

11. The method according to claim 1 characterized by the generation of silicon on insulator (SOI) substrate.

12. The method according to claim 1 characterized by silicon as the substrate (1, 1′).

13. The method according to claim 1 characterized by silicon germanium (SiGe), SiC, sapphire or an oxidic perovskite as the substrate (1, 1′).

14. The method according to claim 1 characterized by silicon germanium (SiGe) as the material of the first epitactic layer (2, 2′, 6, 6′).

15. The method according to claim 1 characterized in that the germanium concentration in a silicon germanium (SiGe) layer can be varied.

16. The method according to claim 1 characterized by compound semiconductors of the III-V group of the periodic system, the nitride of group III-V of the periodic system (AlN, GaN, or InN) or of the II-VI groups, or oxidic perovskite as the material of the first epitactic layer (2, 2′, 6, 6′).

17. The method according to claim 1 characterized by shallow trench insulation (STI), deep trench insulation or LOCOS as insulation regions (3, 3′).

18. The method according to claim 1 characterized in that as the second epitactic layer (7, 7′) a silicon layer, silicon germanium (SiGe) layer or germanium layer or a multiplicity of layers is deposited over the entire area or selectively of the layer sequence.

19. The method according to claim 1 characterized in that in case of silicon germanium as the second epitactic layer (7, 7′) on silicon germanium (SiGe) as the first epitactic layer (6,6′) the germanium concentration of the layer (7,7′) is higher than that in the layer (6,6′).

20. The method according to claim 1 characterized in that a trough implantation is carried out for component production and a defect implantation for stress relaxation with the same mass.

21. The method according to claim 1 characterized in that selected insulating regions (3, 3′) are removed at least up to in the depth of the first epitactic layer (2, 2′, 6, 6′).

22. The method according to claim 1 characterized in that the first epitactic layer (2, 2′, 6, 6′) is at least locally removed to produce stressed silicon on “nothing”, (silicon on nothing, SON).

23. The method according to claim 1 characterized in that the removed region from the first epitactic layer (2, 2′, 6, 6′) is filled with an insulator (17, 17′) to produce silicon on insulator (SOI).

24. The method according to claim 1 characterized in that the layer sequence is planarized.

25. The method according to claim 1 characterized in that the stressed silicon regions (7, 7′) are processed to n MOSFETs.

26. The method according to claim 1 characterized in that the stressed silicon germanium (SiGe) regions (2, 2′, 7, 7′) are processed into p-MOSFETs.

27. The method according to claim 1 in which etched trenches are produced in the depth of the layer.

28. The method according to claim 1 characterized in that after forming the etched trenches a relaxation of layers is carried out especially by a heat treatment.

29. A component with one or more layers produced by a method according to claim 1.

30. A transistor, especially a modulated doped field effect transistor (MODFET) or a metal oxide semiconductor field effect transistor (MOSFET) as the component according to claim 29.

31. A resonant tunnel diode, especially a resonant silicon germanium (SiGe) tunnel diode as the component of claim 29.

32. A photo detector as the component according to claim 29.

33. A laser as the component according to claim 29.
